(19) United States
(12) Patent Application Publication
(10) Pub. No.: US 2025/0005217 A1
(43) Pub. Date: Jan. 2, 2025

(54) Method and Control System for a Technical Installation

(71) Applicant: Siemens Aktiengesellschaft, Muenchen (DE)

(72) Inventor: Benjamin LUTZ, Pfintal (DE)

(21) Appl. No.: 18/754,891

(22) Filed: Jun. 26, 2024

(30) Foreign Application Priority Data
Jun. 30, 2023 (EP) 23182852

(51) Int. Cl. G06F 30/13

(52) U.S. Cl. CPC G06F 30/13

(57) ABSTRACT

A control system for a manufacturing or process installation includes at least one operator station server and at least one operator station client connected to the operator station server, wherein the operator station server is configured to transfer visualization information to the operator station client, where the visualization information comprises a plurality of exchangeable installation images and where the operator station client is configured to present the visualization information with the exchangeable installation images to an operator of the manufacturing or process installation, where the control system is configured to present the operator of the manufacturing or process installation, at the runtime of the manufacturing or process installation, with a test image that differs from the installation images and that comprises a color region having the colors used in at least two of the installation images of the visualization information.

### BACKGROUND OF THE INVENTION

### 1. Field of the Invention

The invention relates to method for operating a control system for a manufacturing or process installation and a control system for a manufacturing or process installation, which comprises at least one operator station server and at least one operator station client connected to the operator station server, where the operator station server is configured to transfer visualization information to the operator station client, where the visualization information comprises a plurality of exchangeable installation images, and where the operator station client is configured to present the visualization information with the exchangeable installation images to an operator of the manufacturing or process installation.

### 2. Description of the Related Art

Symbolic installation images that represent the process engineering relationships (particularly between the process objects) in an abstract manner are created to operate and monitor process engineering installations. In this context, installation images are composed of static symbols (for example, lines, rectangles), dynamic symbols (for example, lines that change color as a function of process values, rectangles with fill levels), block symbols (for the dynamic visualization of process engineering process objects), complex controls (for example, trend displays, message sequence displays), containers for visualizing contents from independent, stand-alone sources (for example, webcams, installation images of modular installation sections (package units) or apps (for example, controller optimizers, KPI calculations).

Furthermore, installation images can also comprise numerous text fields for describing measuring points or inserting comments, for example. Here, the color scheme of symbols and the like is usually based on symbolic colors, which are preconfigured centrally during the engineering of the process installation and used in the different editors. In order to be able to represent events visually in an improved manner, installation image contents can be made to flash at different frequencies as a function of process engineering states.

The properties of the installation images are configured during engineering at corresponding workplaces, where it is not possible to assess the installation images thus produced under all boundary conditions under which they are used for operation and monitoring. This means that the installation images cannot be checked for accessibility during engineering as not all the boundary conditions are known, such as the operator's individual eyesight capacity, the output devices actually used (from mobile terminal device through to large screen in control room) or the ambient conditions (from dimmed control station through to direct sunlight in the field).

EP 3 876 046 A1 discloses a control system of a technical installation that enables visualization information presented by an operator station client to be adjusted by an operator at a runtime of the technical installation.

### SUMMARY OF THE INVENTION

It is an object of the invention is to provide a control system for a process or manufacturing installation in which the individual and environment-dependent accessibility of the configured installation images can, if necessary, be checked ad hoc at runtime to ensure that, in the present situation, all relevant aspects of the installation images provided can also be perceived for safe operation and monitoring.

This and other objects and advantages are achieved in accordance with the invention by a method for operating a control system for a manufacturing or process installation and a control system for the process or manufacturing installation comprising at least one operator station server and at least one operator station client connected to the operator station server, where the operator station server is configured to transfer visualization information to the operator station client, where the visualization information comprises a plurality of exchangeable installation images, and where the operator station client is configured to present the visualization information with the exchangeable installation images to an operator of the manufacturing or process installation.

The control system in accordance with the invention is advantageously configured to present the operator of the manufacturing or process installation, at the runtime of the manufacturing or process installation, with a test image that differs from the installation images and that comprises a color region having the colors used in at least two of the installation images of the visualization information.

The technical installation can be an installation from the process industry, such as a chemical, pharmaceutical or petrochemical installation, or an installation from the food and beverage industry. This also encompasses any installations from the production industry, factories in which, for example, automobiles or goods of all kinds are produced.

In the present context, a control system is understood to mean a computer-aided technical system, which comprises functionalities for representing, operating and controlling the process engineering installation. The control system can further comprise sensors for determining measured values, as well as various actuators. The control system can also comprise what are known as process-oriented or manufacture-oriented components, which serve to activate the actuators or sensors. Furthermore, the control system can have inter alia means for visualizing the process engineering installation and for engineering. The control system can optionally also comprise further computing units for more complex closed-loop controls and systems for data storage and data processing.

In the present context, an “operator station server” is understood to mean a server that centrally captures data of an operating and monitoring system and generally also alarm and measured value archives of a control system of a technical installation, and that makes this data available to users. The operator station server generally establishes a communication connection to automation systems of the technical installation and forwards data of the technical installation for visualization purposes to what are known as operator station clients, which serve to control and monitor an operation of the individual functional elements of the technical installation. The operator station server can have client functions for accessing the data (archives, messages, tags, variables) of other operator station servers.

This means that images of an operation of the technical installation on the operator station server can be combined with variables of other operator station servers (server-server communication). The operator station server can be a SIMATIC PCS 7 industrial workstation server from SIEMENS, without being restricted thereto.

An operator of the technical installation can access the operation station server via the operator station client, which can be, for example, a tablet, a smartphone, a personal computer or the like, for purposes of operating and monitoring the technical installation.

In the present context, visualization is understood to mean the graphical presentation to the operator which occurs via the operator station client. The operator station client generally has corresponding functionalities enabling it to use relevant visualization information that it receives from the operator station server to generate the intended visualization. Here, the visualization can generally comprise, in a manner known per se, installation images, graphical windows displaying progressions of measured values, message displays, graphical objects representing technical objects of the technical installation, and the like. In the case of a process installation, such an image installation can comprise, for example, graphical representations of pumps, valves, tanks, pipes, and/or combustion chambers. Here, the graphical representations can comprise current process measured values, status values, (alarm) messages or the like.

The control system in accordance with the invention is configured to visually present the operator with a separate test image, which differs from the actual installation images, at the runtime of the technical installation, i.e., during operation of the technical installation. This test image comprises the colors of at least two of the installation images that were generated and made available to the operator station server during the engineering of the manufacturing or process installation, i.e., during configuration of the automation for the manufacturing or process installation. Here, the colors can be represented in any manner. For example, circles or squares having the colors used in the at least two installation images can be represented.

With the aid of the test image, the operator can check the color scheme recognizable to them directly in the situation in which they would like to use installation images for operating and monitoring the manufacturing or process installation, and make any corrections that may be required. In this context, the operator can check, for example, whether they can correctly recognize yellow and red colors, as these indicate warnings or alarms and the operator must be able to recognize these colors immediately and clearly. Predefined symbolic colors, which are defined centrally during engineering, are generally used during the configuration/engineering of the installation images. Here, for example, the medium “water”, the alarm class “critical” and so on always have the same color tone. The symbolic colors are therefore of central importance, and steps must be taken to ensure that a clear distinction can also be made between the different colors. To enable this to be checked, the symbolic color palette is positioned in the automatically generated “Visualization Validation” installation image.

The test image takes the colors of at least two installation images into consideration. All installation images generated during engineering and transferred to the operator station server are preferably taken into consideration for the test image.

In addition to the colors, the test image can also comprise a text region having the fonts and font sizes used in the installation images. Installation images generally contain several text fields and a wide variety of texts to designate symbols, measuring points, and so on. The texts can be configured in different fonts and font sizes in the installation images. Here, all fonts and font sizes used in the (at least two, preferably all) installation images can be taken into consideration and represented in the test image. It is, however, also possible for just the smallest font size used in the installation images to be represented. As a result, the operator can establish directly whether they can also correctly recognize all texts/fonts.

Intermediate variables can also be taken into consideration in the test image in order to better be able to recognize the “legible” transitions. Depending on the output device, lighting conditions and visual acuity, the operator can thus check individually whether they are currently in a position to decipher the smallest texts present in an installation image.

The test image particularly preferably comprises a flashing region having the flashing frequencies used in the installation images. Symbols or status displays can be rendered dynamic in installation images by way of flashing with different frequencies. Here, the perceptibility of the flashing frequency can vary depending on the terminal device, ambient influences and the like. Here, the flashing frequencies configured in the installation images can be visualized via status symbols to be checked by the operator.

The test image can also comprise a symbol region, which comprises symbol images used in the installation images and selected according to certain criteria. Symbols (which have been rendered dynamic) are used for the abstract graphical representation of process engineering processes. For the test image, some of the graphical symbols can be determined and positioned so that the operator can check individually and depending on the ambient conditions whether they can perceive the symbols and their dynamic representation in detail. The symbol images are preferably selected according to their size such that the symbol region comprises a number, to be determined, of the smallest symbol images.

The operator of the manufacturing or process installation can preferably specify at the runtime of the manufacturing or process installation which of the installation images are to be taken into consideration for generating the test image. Here, the operator can specify in a variable manner, for example, whether they want installation image X and installation image Y to be taken into consideration for generating the test image because these two installation images are of particular relevance to them.

Within the context of a preferred development of the invention, the control system is configured, upon selection of a region of the test image, to visually present the operator with the installation image that was taken into consideration when generating the region. If the operator selects, for example, a color in the color region or a font in the text region, then the operator station server or the operator station client presents them with the installation image that comprises the color or the font. This enables the operator to establish that installation image could potentially present them with difficulties. In addition, they see the color or the font in the context of the relevant installation region and as a result can better judge whether perception problems may actually arise.

The control system is preferably configured to generate an alarm message that is associated with the test image and can be acknowledged by the operator. Here, an alarm message is a message that generally requires a prompt response from an operator of the technical system. Here, a message is understood to mean a report about the occurrence of an event which represents a transition from one discrete state within the technical system to another discrete state. The (unacknowledged) alarm message makes it clear to the affected operator or further operators that the assessment of the test image by the operator is still outstanding. An alarm message can also be easily integrated into existing alarm message mechanisms of the control system.

Here, the control system is preferably configured to withhold a visual presentation of the installation images from the operator until the alarm message associated with the test image has been acknowledged. In other words, the operator must actively acknowledge the test image before they can use the installation images taken into consideration by the test image for operating and monitoring purposes. This makes it possible to ensure that the installation images are actually checked for “accessibility”.

The alarm message can be configured such that the operator can make comments on it. These comments can be read, for example, by a configuration engineer for the manufacturing or process installation, who can perform an adjustment to the installation images. Here, the operator can inform the configuration engineer or other operators, for example, that they cannot correctly recognize the color “red” in installation image Z or the text in installation image XY, whereupon the configuration engineer can, for example, perform an adjustment to the contrast or color saturation.

The generation of the alarm message is preferably dependent on a location and/or an identity and/or a role of the operator. For example, the acknowledgment of the alarm message can be particularly important if the operator is located in a particular environment (dark, foggy, scattered light, and so on).

The objects and advantages are also achieved in accordance with the invention by a method for operating a control system for a manufacturing or process installation, which comprises at least one operator station server and at least one operator station client, where the operator station server is configured to transfer visualization information to the operator station client, where the visualization information comprises a plurality of exchangeable installation images, and where the operator station client is configured to present the visualization information with the exchangeable installation images to an operator of the manufacturing or process installation. In accordance with the method, the control system presents the operator of the manufacturing or process installation, at the runtime of the manufacturing or process installation, with a test image comprising a color region having the colors used in at least two of the installation images of the visualization information.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The above-described properties, features and advantages of this invention and the manner in which these are achieved will now be described more clearly and intelligibly in relation to exemplary embodiments, and illustrated in detail by reference to the drawings, in which:

FIG. 1 shows a graphical presentation of a test image in accordance with a first embodiment of the invention;

FIG. 2 shows a graphical presentation of an installation image in accordance with the invention;

FIG. 3 shows a graphical presentation of a test image in accordance with a second embodiment of the invention;

FIG. 4 shows a schematic representation of a control system in accordance with the invention; and

FIG. 5 is a flowchart of the method in accordance with the invention.

### DETAILED DESCRIPTION OF THE EXEMPLARY EMBODIMENTS

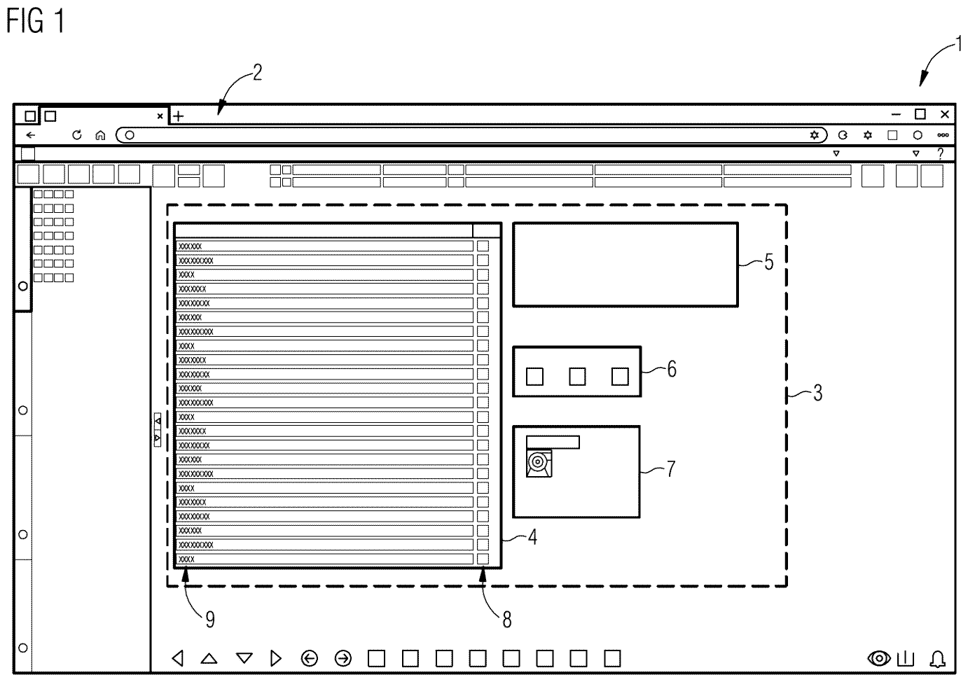

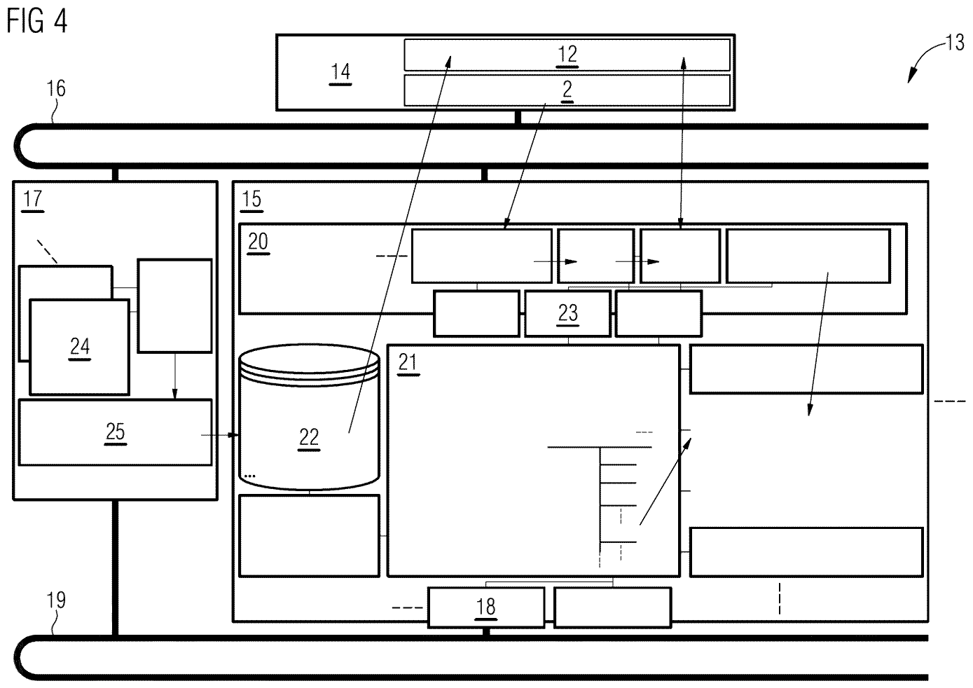

FIG. 1 shows a visualization 1 presented by an operator station client (cf. FIG. 4) to an operator of a process installation for operating and monitoring the process installation. In addition to operating elements 2 (not described in more detail here), the visualization comprises a test image 3, which is indicated with a dashed border in FIG. 1 to make it more recognizable.

The test image 3 has a color region 4, a text region 5, a flashing region 6 and a symbol region 7.

In the color region 4, all colors used in the different installation images of an automation system for the process installation are shown in a column 8. Here, the installation images are used for operating and monitoring the process installation. The colors are each represented in a square shape. In a name column 9, shown to the left of the color column 8 in FIG. 1, a designation such as “Closed”, “Active” or “Stopped” is shown in each case, depending on how the respective color is used in the installation images.

A selection of the fonts used in the installation images is shown in the text region 5. Here, for example, the five fonts with the smallest font sizes and the five fonts with the largest font sizes can be shown in the text region 5.

The flashing animations used in the installation images are shown in the form of flashing squares in the flashing region 6. Here, the squares are shown separately in accordance with the flashing frequency used.

In the symbol region 7, for example, the five smallest symbols used in the installation images are shown. FIG. 1 shows just one symbol by way of example.

When the operator selects one of the regions 4, 5, 6, 7 of the test image 3, the operator is visually presented with the installation image that was taken into consideration when generating the region 4, 5, 6, 7. If, for example, the operator clicks or taps on the text “Extraction”, then the installation image in which the text “Extraction” is used is shown by the control system or the associated operator station client (cf. FIG. 4). The operator can thus easily and quickly experience the context in which the text appears.

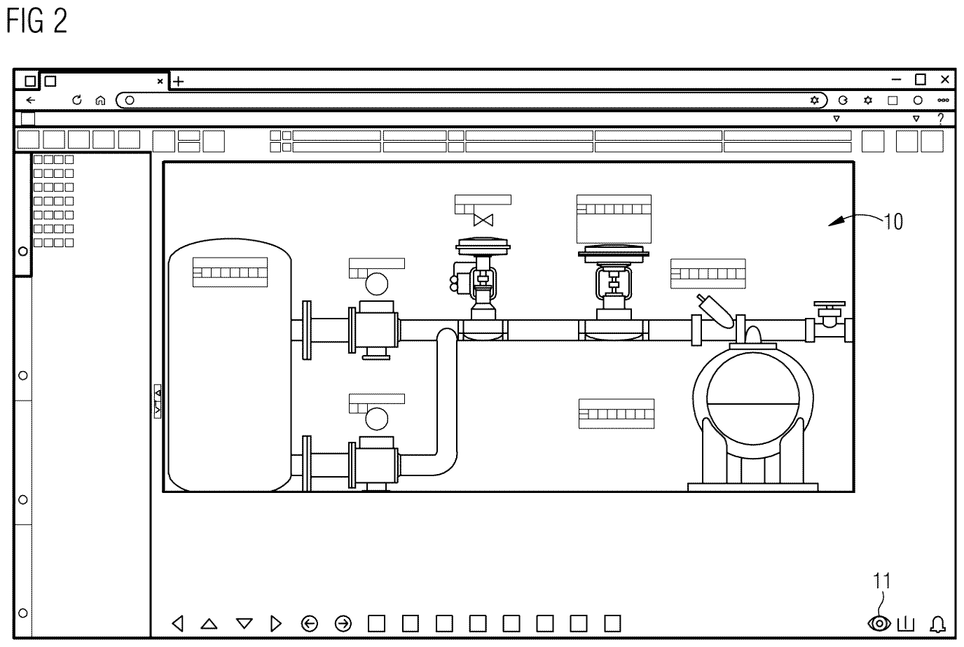

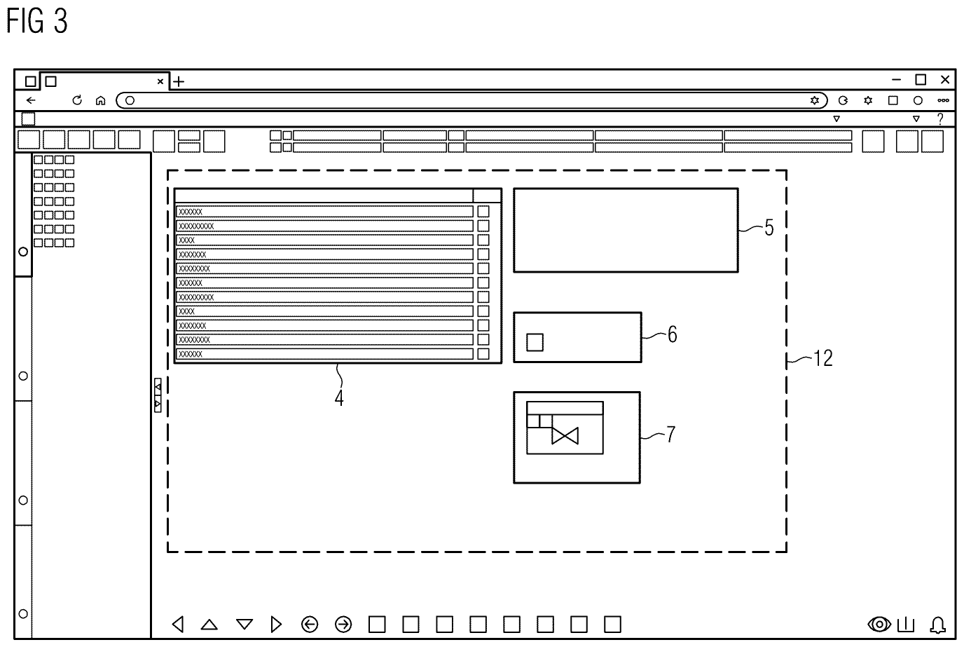

The installation images underlying the test image can have been determined in an engineering or configuration phase of the automation system for the process installation. It is, however, also possible for the operator to determine directly at the runtime of the process installation which installation image is to be taken into consideration for the test image 2. FIG. 2 shows an installation image 10, which the operator can take into consideration for a test image. To this end, the operator must simply select a corresponding prompt symbol 11 (by clicking on it with the mouse or tapping on it with a finger). As a result, the installation image 10 is taken into consideration for the test image 12 (cf. FIG. 3).

The test image 12 shows the operator the same regions 4, 5, 6, 7, which however now have only contents which are included in the installation image 10. This “ad hoc” functionality allows the operator to check for each installation image whether they can also correctly recognize the contents represented in the opened installation image. This can be particularly relevant when they would like to operate and monitor the process installation in the field using a mobile terminal device in strong sunlight.

FIG. 4 shows a schematic representation of a control system 13 for operating and monitoring the process installation. The control system 13 comprises an operator station client 14 and an operator station server 15 that is connected to the operator station client 14. The operator station server 15 and the operator station client 13 are connected to one another and connected to an engineering station server 17 of the control system 13 via a terminal bus 16.

A user or operator can access the operator station server 15 via the operator station client 14 via the terminal bus 16 for operation and monitoring purposes. The terminal bus 16 can be formed as an industrial Ethernet, for example, without being limited thereto.

The operator station server 15 has a device interface 18 that is connected to an installation bus 19. With this device interface 18, the operator station server 15 can communicate with an automation device (not shown) as well as with optionally present further components of the process engineering installation, such as peripheral devices (not shown). The installation bus 19 can be formed as an industrial Ethernet, for example, without being limited thereto.

A visualization service 20, a process image 21 and a configuration memory 22 are implemented (inter alia) on the operator station server 15. The visualization service 20 integrated in the operator station server 15 initiates a transfer of visualization information to the operator station client 14. The operator station client 14 is configured to represent a visualization, i.e., a graphical presentation, in particular of installation images, for operating and monitoring the process installation.

Recorded in the process image 21 of the operator station server 15 is a snapshot of the (signal) states of devices and/or applications (not shown in the figure) connected to the operator station server 15. An alarm service 23 can read out alarm messages from the process image 21 and, for example, generate a graphical aggregation of the alarm messages, which the operator station client 14 can display.

In a configuration tool 24, inter alia, installation images 10 are generated for operation and monitoring of the process installation and loaded via a loading service 25 into the configuration memory 22 of the operator station server 15. The test image 2 is likewise generated by the engineering station server 17 and stored in the configuration memory 22. The visualization service 20 uses this information to present the installation images 10 and the test image 2 to the operator.

If the operator initiates the test image 12 directly at the runtime of the process installation, a subservice 26 of the visualization service 15 accesses the data associated with the installation images 10 from the configuration memory 22 and generates the desired test image 12.

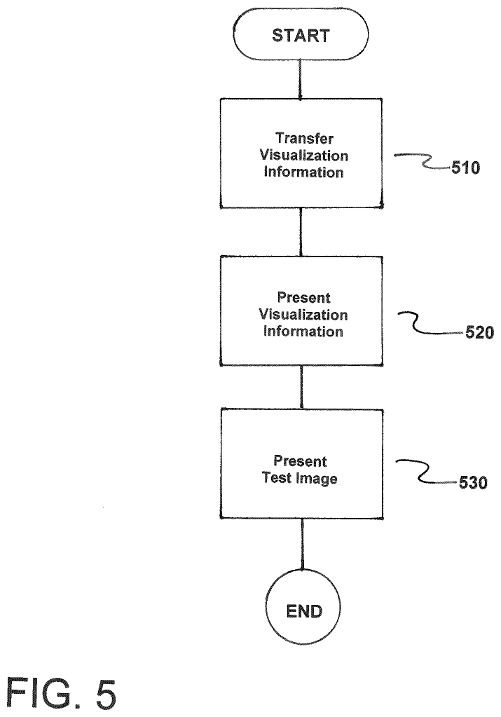

FIG. 5 is a flowchart of the method for operating a control system 13 for a manufacturing or process installation, which comprises at least one operator station server 15 and at least one operator station client 14. The method comprises transferring, by the operator station server 15, visualization information to the operator station client 14, the visualization information comprises a plurality of exchangeable installation images 10, as indicated in step 510.

Next, the operator station client 14 presents the visualization information with the exchangeable installation images 10 to an operator of the manufacturing or process installation, as indicated in step 520.

Next, the control system 13 presents the operator of the manufacturing or process installation, at the runtime of the manufacturing or process installation, with a test image 3, 12 comprising a color region 4 having the colors used in at least two of the installation images 10 of the visualization information, as indicated in step 530.

Although the invention has been illustrated and described in detail using the preferred exemplary embodiment, the invention is not limited by the disclosed examples, and a person skilled in the art can derive other variations therefrom without departing from the scope of protection of the invention.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A control system for a manufacturing or process installation, the system comprising:
at least one operator station server; and
at least one operator station client connected to the operator station server, the operator station client being configured to present visualization information with exchangeable installation images to an operator of the manufacturing or process installation;
wherein the at least one operator station server is configured to transfer the visualization information to the at least one operator station client, the visualization information comprising a plurality of exchangeable installation images; and
wherein the control system is configured to present the operator of the manufacturing or process installation, at runtime of the manufacturing or process installation, with a test image which differs from the installation images and comprises a color region having colors utilized in at least two of the installation images of the visualization information.

2. The control system as claimed in claim 1, wherein the test image comprises a color region having colors utilized in all installation images of the visualization information.

3. The control system as claimed in claim 1, wherein the test image comprises a text region having fonts and font sizes utilized in the installation images.

4. The control system as claimed in claim 2, wherein the test image comprises a text region having fonts and font sizes utilized in the installation images.

5. The control system as claimed in claim 1, wherein the test image comprises a flashing region having flashing frequencies utilized in the installation images.

6. The control system as claimed in claim 1, wherein the test image comprises a symbol region having symbol images, selected in accordance with certain criteria, contained in the installation images.

7. The control system as claimed in claim 6, wherein the symbol images are selected in accordance with their size such that the symbol region comprises a number, to be determined, of the smallest symbol images.

8. The control system as claimed in claim 1, wherein the operator of the manufacturing or process installation can specify, at the runtime of the manufacturing or process installation, which of the installation images are to be taken into consideration for generating the test image.

9. The control system as claimed in claim 1, wherein the control system is configured to, upon selection of a region of the test image, visually present the operator with the installation image which was taken into consideration when generating the region.

10. The control system as claimed in claim 1, wherein the control system is configured to generate an alarm message which is associated with the test image and acknowledgeable by the operator.

11. The control system as claimed in claim 10, wherein the control system is configured to withhold a visual presentation of the installation images from the operator until the alarm message associated with the test image has been acknowledged.

12. The control system as claimed in claim 10, wherein the alarm message is configured such that the operator can make comments on it.

13. The control system as claimed in claim 11, wherein the alarm message is configured such that the operator can make comments on it.

14. The control system as claimed in claim 10, wherein the generation of the alarm message is dependent on at least one of a location, an identity and a role of the operator.

15. The control system as claimed in claim 11, wherein the generation of the alarm message is dependent on at least one of a location, an identity and a role of the operator.

16. The control system as claimed in claim 11, wherein the generation of the alarm message is dependent on at least one of a location, an identity and a role of the operator.

17. A method for operating a control system for a manufacturing or process installation, which comprises at least one operator station server and at least one operator station client, the method comprising:
transferring, by the operator station server, visualization information to the operator station client, the visualization information comprises a plurality of exchangeable installation images;
presenting, by the operator station client, the visualization information with the exchangeable installation images to an operator of the manufacturing or process installation; and
presenting, by the control system, the operator of the manufacturing or process installation, at the runtime of the manufacturing or process installation, with a test image comprising a color region having the colors used in at least two of the installation images of the visualization information.

18. The method as claimed in claim 17, wherein the operator of the manufacturing or process installation specifies which of the installation images are to be taken into consideration for generating the test image.

19. The method as claimed in claim 17, wherein the control system generates an alarm message which is associated with the test image and which is acknowledgeable by the operator.

20. The method as claimed in claim 19, wherein the control system generates an alarm message which is associated with the test image and which is acknowledgeable by the operator.
